(19) United States
(12) Patent Application Publication
(10) Pub. No.: US 2013/0083459 A1
(43) Pub. Date: Apr. 4, 2013

(54) ELECTRONIC ASSEMBLY HAVING RETENTION DEVICE FOR DATA STORAGE MODULE

(71) Applicants: YUN-LUNG CHEN, Tu-Cheng (TW); LIANG-CHIN WANG, Tu-Cheng (TW); LI TONG, Wuhan City (CN); JUN-ZHI XU, Wuhan City (CN)

(72) Inventors: YUN-LUNG CHEN, Tu-Cheng (TW); LIANG-CHIN WANG, Tu-Cheng (TW); LI TONG, Wuhan City (CN); JUN-ZHI XU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/437,126

(22) Filed: Apr. 2, 2012

(30) Foreign Application Priority Data
Sep. 30, 2011 (CN) 201110297330.8

(51) Int. Cl. H05K 7/00

(52) U.S. Cl. 361/679.01; 248/309.1

(57) ABSTRACT

A retention device includes a holder and a fixture. The holder defines a first cavity with a first opening at a front end thereof. The fixture is mounted to the holder through the first opening and comprises a base and a bracket detachably mounted on the base. The base and the bracket cooperatively define a second cavity. A size of the second cavity is smaller than that of the first cavity.

### BACKGROUND

1. Technical Field

The disclosure relates to retention devices and, more particularly, to a retention device for a data storage module of an electronic apparatus.

2. Description of Related Art

An electronic apparatus, such as a desktop computer, tower computer, or server, can include storage modules, such as hard disk drives, compact disk read-only memory drives, and digital video disc drives. These devices increase the functionality of the electronic apparatus.

A retention device holds a storage module such as a hard disk drive in a computer. However, the retention device may be rigid and fixed and allow only one type of data storage modules having a unique configuration. If the data storage module of an electronic apparatus is changed, the retention device may also need to be replaced.

Therefore, what is needed is a retention device which can overcome the shortcomings described above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, all the views are schematic, and like reference numerals designate corresponding parts throughout the several views.

FIG. 1 is an assembled view of one embodiment of a retention device and a second storage module.

FIG. 2 is a disassembled view of the retention device and the second storage module of FIG. 1.

FIG. 3 is a partially assembled view of the retention device and the second storage module of FIG. 2.

FIG. 4 is an assembled view of another embodiment of a retention device and a first storage module.

### DETAILED DESCRIPTION

Reference will be made to the drawings to describe the present embodiment of a retention device.

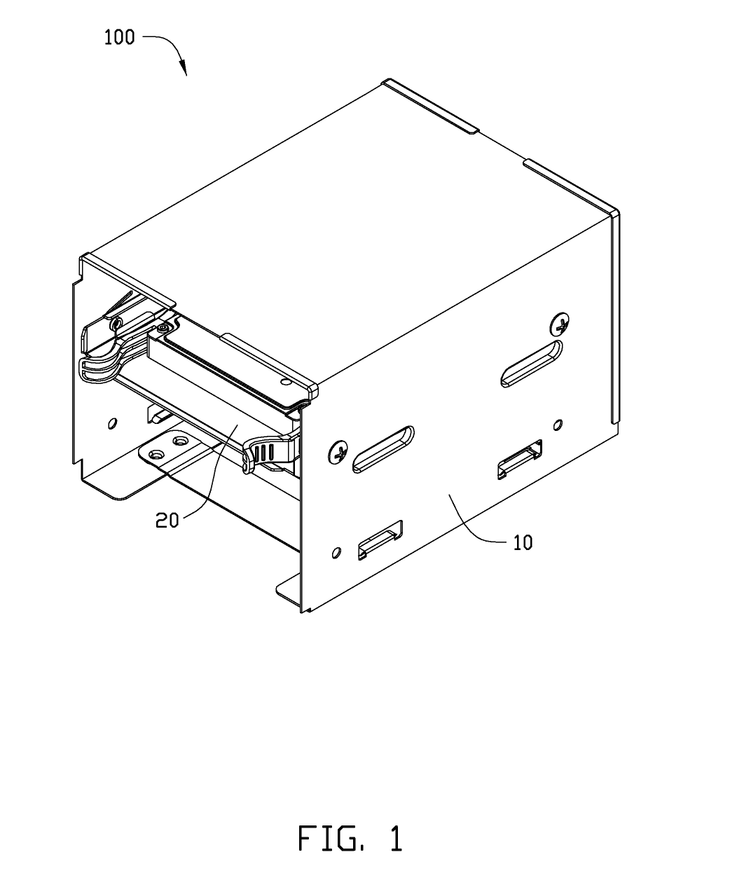

Referring to FIG. 1, an embodiment of a retention device 100 includes a holder 10 and a fixture 20. The retention device 100 receives and fixes in place a storage module.

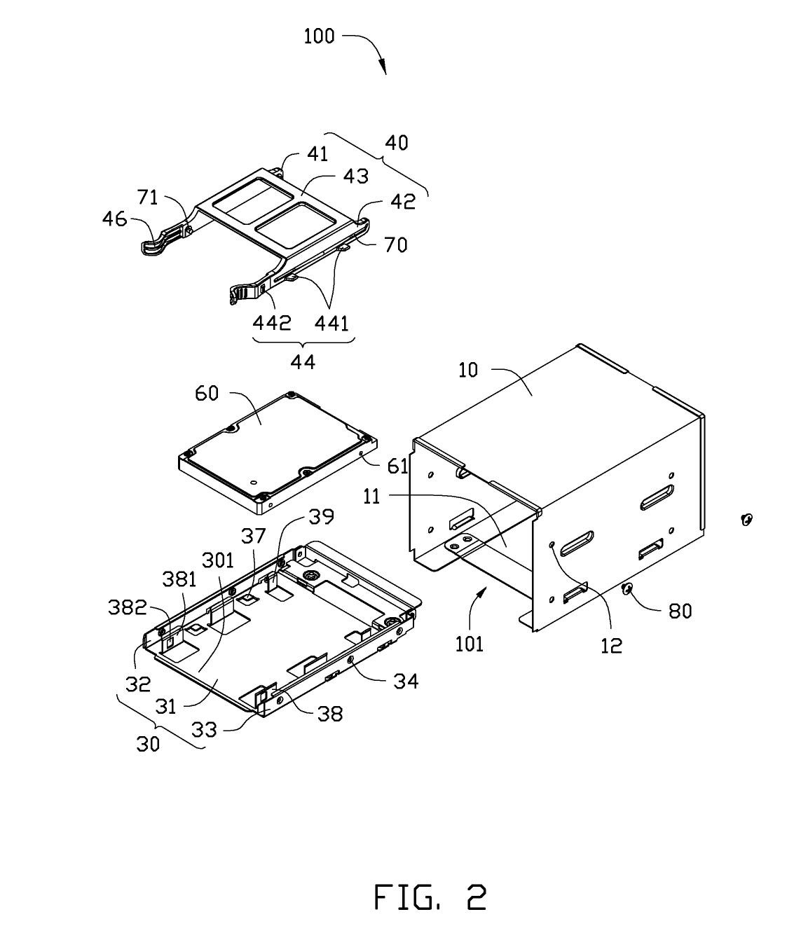

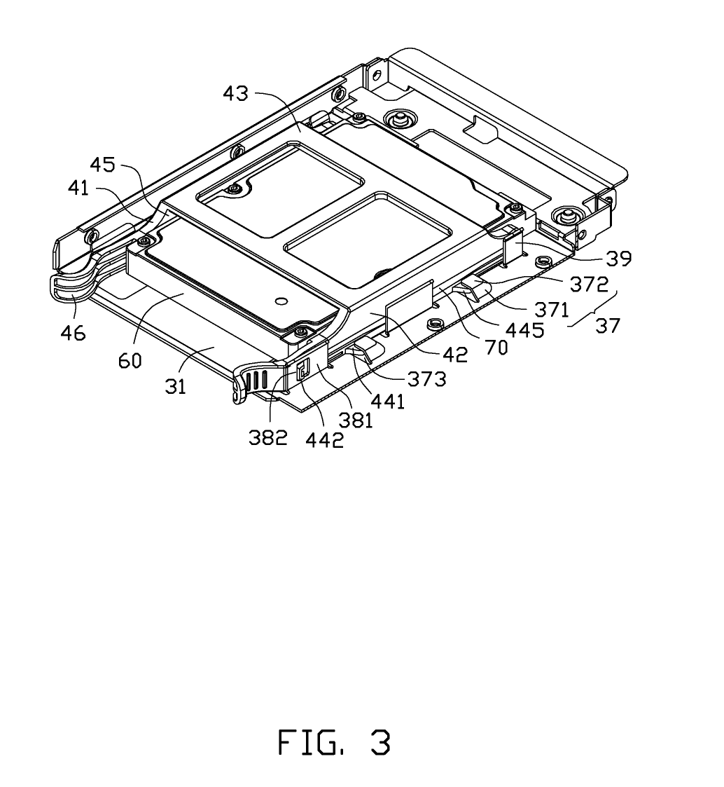

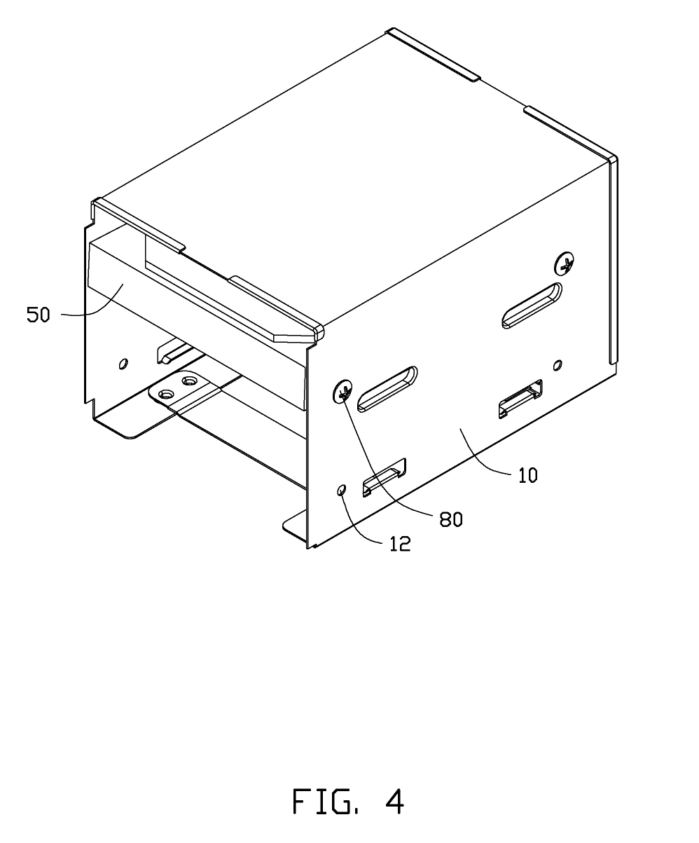

Referring to FIGS. 2 and 3, the holder 10 defines a rectangular first cavity 11 with a first opening 101 at a front end thereof. The first cavity 11 receives a first storage module 50 (shown in FIG. 4). In the present embodiment, two side walls (not labeled) of the holder 10 define a plurality of mounting holes 12 for fixing the first storage module 50 in the holder 10.

The fixture 20 includes a base 30 and a bracket 40 detachably mounted on the base 30. The bracket 40 and the base 30 cooperatively define a rectangular cavity (second cavity 45) housing a second storage module 60. In one embodiment, a size of the second cavity 45 is less than that of the first cavity 11.

In one embodiment, the base 30 is made of metal, and includes a bottom plate 31, a first side wall 32 and a second side wall 33 extending from two opposite lateral sides of the bottom plate 31. In the embodiment, the first side wall 32 and the second side wall 33 are perpendicular to the bottom plate 31. The first side wall 32 and the second side wall 33 each define a plurality of first fixing holes 34. A plurality of fasteners 80 extend through the mounting holes 12 of the holder 10 and the first fixing holes 34 of the first and second side walls 32, 33 to fix the base 30 onto the holder 10. The second cavity 45 has a second opening 301 at a front end of the base 30. The orientation of the second opening 301 is the same as the orientation of the first opening 101 of the holder 10.

In one embodiment, the base 30 includes a plurality of latches mounted on the bottom plate 31. The latches include a plurality of catches 37 and two tabs 38. The catches 37 are arranged on the two opposite sides of the bottom plate 31. Each catch 37 includes a restricting portion 371 extending upwardly from the bottom plate 31 and a pressing portion 372 extending horizontally and inwardly from a free end of the restricting portion 371. In the embodiment, the pressing portion 372 is parallel to the bottom plate 31. The pressing portion 372 and the restricting portion 371 cooperatively define a room 373 having an opening. The tabs 38 are respectively arranged on the two opposite sides of the bottom plate 31 near the second opening 301. Each tab 38 includes a baffling plate 381 extending upwardly from the bottom plate 31. Each baffling plate 381 defines a rectangular through hole 382. In one embodiment, the base 30 further includes a plurality of mounting plates 39 extending upwardly from the bottom plate 31 and located at the two opposite sides of the bottom plate 31. The mounting plates 39 located at the same side of the bottom plate 31 are collinear with the tab 38. The mounting plates 39 assist the catches 37 and tabs 38 to clamp the bracket 40 to the base 30.

The bracket 40 can be made of plastic and includes a first side plate 41, a second side plate 42 opposite to the first side plate 41, a top plate 43 interconnecting the first side plate 41 and the second side plate 42, and a handle 46 extending from the first side plate 41 and from the second side plate 42. The handles 46 are located at front ends of the first and second side plates 41, 42. The first side plate 41 and the second side plate 42 each define a projection set 44 protruding outwardly from an outer surface thereof. Each projection set 44 includes a plurality of first projection portions 441 corresponding to the catches 37 and two second projection portions 442 corresponding to the tabs 38. In one embodiment, each of the first and second side plates 41, 42 has two first projection portions 441, and each side of the bottom plate 31 has two catches 37 for engaging with the first projection portions 441. Each first projection portion 441 includes an inclined surface 445 facing the second opening 301 of the base 30. A width of the first projection portion 441 gradually decreases away from the first and second side plates 41, 42. Each of the second projection portions 442 is located at the front end of the first side plate 41 and the second side plate 42. Each of the second projection portions 442 is located between a handle 46 and the first projection portions 441 of the first side plate 41 and the second side plate 42. The bracket 40 can be assembled to the base 30 by first abutting each first projection portion 441 against a restricting portion 371, and each second projection portion 442 is received in the through hole 382 of the tab 38, to fix the bracket 40 onto the base 30. The second cavity 45 is defined by the bottom plate 31 of the base 30, the top plate 43, the first side plate 41 and the second side plate 42 of the bracket 40. The mounting plates 39 are located at the sides of the bracket 40.

In one embodiment, the retention device 100 further includes two rods 70 located on outer walls of the first side plate 41 and the second side plate 42. In one embodiment, outer sidewalls of the second storage module 60 define a plurality of second fixing holes 61. An end 71 of each of the two rods 70 extends through the outer wall of the first side plate 41 and of the second side plate 42, and then engages in the second fixing holes 61 to fix the second storage module 60 onto the bracket 40.

The retention device 100 can receive and firmly hold storage modules with different sizes. In one embodiment, the second storage module 60 is held in the fixture 20, and the fixture 20 can be received in the holder 10. In another embodiment as shown in FIG. 4, the retention device 100 can receive the first storage module 50 directly in the holder 10. A size of the second storage module 60 is less than that of the first storage module 50.

The second storage module 60 can be assembled in the retention device 100 by first extending the ends 71 of each rod 70 through the outer walls of the first and second side plates 41 and 42, and engaging in the second fixing holes 61, thereby fixing the second storage module 60 on the bracket 40. In one embodiment, the retention device 100 further includes a plurality of fasteners 80 extending through the mounting holes 12 and the first fixing hole 34 of the base 30 to fix the base 30 on the holder 10. The handles 46 can be pressed inwards to allow the bracket 40 to be mounted on the base 30. As a result, the second storage module 60 is received in the second cavity 45 of the fixture 20 and fixed on the retention device 100.

FIG. 4 shows the retention device 100 receiving the first storage module 50.

When the second storage module 60 is replaced with the first storage module 50, the fixture 20 is first removed from the holder 10, and the first storage module 50 is directly mounted onto the holder 10. The fasteners 80 can extend through the mounting holes 12 and second fixing holes (not shown) of the first storage module 50 to fix the first storage module 50 on the holder 10.

Although numerous characteristics and advantages have been set forth in the foregoing description of the one or more embodiments, together with details of the structures and functions of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A retention device comprising:
a holder defining a first cavity with a first opening at a front end thereof; and
a fixture mounted to the holder through the first opening and comprising a base and a bracket detachably mounted on the base, wherein the base and the bracket cooperatively define a second cavity, and a size of the second cavity being smaller than that of the first cavity.

2. The retention device of claim 1, wherein the base comprises a bottom plate, two side walls extending from two opposite lateral sides of the bottom plate and fixed on the holder, and a plurality of latches arranged on the bottom plate of the base.

3. The retention device of claim 2, wherein the bracket comprises two side plates and a top plate interconnecting the side plates, a plurality of projection sets protrudes outwardly from an outer surface of the side plates, the projection sets engaging with the latches to fix the bracket on the base, the second cavity being defined by the bottom plate of the base, the top plate, and the two side plates of the bracket.

4. The retention device of claim 3, wherein the latches comprise a plurality of catches, each catch comprising a restricting portion extending upwardly from the bottom plate and a pressing portion extending horizontally and inwardly from a free end of the restricting portion.

5. The retention device of claim 4, wherein the projection sets each comprises a plurality of first projection portions engagingly received in the catches and abutting a corresponding restricting portion to fix the bracket on the base.

6. The retention device of claim 3, wherein the latches comprises a plurality of fasteners, each fastener comprising a baffling plate extending upwardly from the bottom plate of the base, the baffling plate defining a through hole thereof, the projection sets comprising a plurality of second projection portions engagingly received in the through holes of the fasteners.

7. The retention device of claim 1, wherein the fixture defines a second opening at a front end thereof, the bracket further comprises two handles extending from and located at front ends of the side plates and at the second opening of the fixture.

8. The retention device of claim 1, wherein the fixture further comprises two rods respectively located at outer walls of the side plates of the bracket, ends of rods respectively extending through the first and second side plates.

9. An electronic assembly comprising:
a holder defining a first cavity therein and a first opening at a front end of the holder;
a fixture detachably mounted in the first cavity of the holder through the first opening, the fixture comprising a base and a bracket detachably mounted in the base, wherein the base and the bracket cooperatively define a second cavity having a size less than that of the first cavity; and
a storage module fixed in the first cavity or the second cavity of the fixture according to a size of the storage module.

10. The electronic assembly of claim 9, wherein the base comprises a bottom plate, two side walls extending from two opposite lateral sides of the bottom plate and fixed on the holder, and a plurality of latches arranged on the bottom plate of the base.

11. The electronic assembly of claim 10, wherein the bracket comprises two side plates, and a top plate interconnecting the side plates, a plurality of projection sets protrudes outwardly from an outer surface of the side plates, the projection sets engaging with the latches to fix the bracket on the base, and the second cavity being defined by the bottom plate of the base, the top plate, and the side plates of the bracket.

12. The electronic assembly of claim 11, wherein the latches comprise a plurality of catches, each catch comprising a restricting portion extending upwardly from the bottom plate and a pressing portion extending horizontally and inwardly from a free end of the restricting portion.

13. The electronic assembly of claim 12, wherein the projection sets each comprises a plurality of first projection portions engagingly received in the catches, and abutting a corresponding restricting portion to fix the bracket on the base.

14. The electronic assembly of claim 11, wherein the latches comprise a plurality of fasteners, each fastener comprising a baffling plate extending upwardly from the bottom plate of the base, the baffling plate defining a through hole thereof, the projection sets comprising a plurality of second projection portions engagingly received in the through holes of the fasteners.

15. The electronic assembly of claim 11, wherein the fixture defines a second opening at a front end of the second cavity, the bracket further comprises two handles extending from and located at front ends of the side plates, and at the second opening of the fixture.

16. An electronic assembly comprising:
a holder defining a first cavity therein and a first opening at a front end of the holder, the first cavity receiving a first storage module therein;
a fixture detachably mounted in the first cavity of the holder through the first opening, the fixture comprising a base and a bracket detachably mounted in the base, wherein the base and the bracket cooperatively define a second cavity receiving a second storage module therein, and a size of the second storage module being less than that of the first storage module.

17. The electronic assembly of claim 16, wherein the base comprises a bottom plate, two side walls extending from two opposite lateral sides of the bottom plate and fixed on the holder, and a plurality of latches arranged on the bottom plate of the base.

18. The electronic assembly of claim 17, wherein the bracket comprise two side plates opposite to the first side plate, and a top plate interconnecting the side plates, a plurality of projection sets protrudes outwardly from an outer surface of the side plates, the projection sets engaging with the latches to fix the bracket on the base, and the second cavity being defined by the bottom plate of the base, the top plate, and the side plates of the bracket.

19. The electronic assembly of claim 18, wherein the latches comprises a plurality of catches, each catch comprising a restricting portion extending upwardly from the bottom plate and a pressing portion extending horizontally and inwardly from a free end of the restricting portion.

20. The electronic assembly of claim 19, wherein the projection sets each comprises a plurality of first projection portions engagingly received in the catches and abutting a corresponding restricting portion to fix the bracket on the base.
